(19) United States
(12) Patent Application Publication
(10) Pub. No.: US 2025/0030376 A1
(43) Pub. Date: Jan. 23, 2025

(54) EQUIPMENT PERFORMANCE CALCULATION DEVICE

(71) Applicant: NTT DOCOMO, INC., Tokyo (JP)

(72) Inventors: Fumiaki IGARASHI, Chiyoda-ku (JP); Masayasu SUMIYA, Chiyoda-ku (JP)

(73) Assignee: NTT DOCOMO, INC., Tokyo (JP)

(21) Appl. No.: 18/711,975

(22) PCT Filed: Oct. 3, 2022
(86) PCT No.: PCT/JP2022/036972

§ 371 Date: May 21, 2024

(30) Foreign Application Priority Data
Dec. 15, 2021 (JP) 2021-203198

(51) Int. Cl. H02S 10/20; G01R 22/06; H02S 50/10

(52) U.S. Cl. CPC H02S 10/20; G01R 22/06; H02S 50/10

(57) ABSTRACT

An equipment performance calculation device is a device for calculating the performance of at least one of a power generation device and a storage battery for a base station including the power generation device using renewable energy and the storage battery, and includes a calculation information acquisition unit that acquires power consumption amount information related to a power consumption amount of the base station, power generation amount information indicating a power generation amount of the power generation device, and facility information related to a facility present in an area including a position of the base station, and a performance calculation unit that calculates the performance based on the power consumption amount information, the power generation amount information, and the facility information acquired by the calculation information acquisition unit.

### TECHNICAL FIELD

The present invention relates to an equipment performance calculation device that calculates the performance of equipment installed in a base station.

### BACKGROUND ART

In the related art, the base station used in a mobile communication system includes a solar power generation device and a storage battery (for example, see Patent Literature 1). It is possible to cause the base station to be a completely independent base station, which is a base station that does not rely on commercial power, by operating the base station with power generated by a power generation device based on renewable energy such as a solar power generation device and stored in the storage battery.

### CITATION LIST

### Patent Literature

[Patent Literature 1] Japanese Unexamined Patent Publication No. 2002-330095

### SUMMARY OF INVENTION

### Technical Problem

The performance of the power generation device and the storage battery included in the base station needs to be determined by appropriately considering an environment at a position of the base station. However, a determination method that sufficiently takes the environment into account has not been proposed in the related art.

An embodiment of the present invention has been made in view of the above, and an object of the present invention is to provide an equipment performance calculation device capable of calculating the performance of equipment included in the base station by appropriately considering an environment at a position of the base station.

### Solution to Problem

In order to achieve the above object, an equipment performance calculation device according to an embodiment of the present invention is a performance calculation device for calculating the performance of at least one of a power generation device and a storage battery for a base station including the power generation device using renewable energy and the storage battery, the performance calculation device including: a calculation information acquisition unit configured to acquire power consumption amount information related to a power consumption amount of the base station, power generation amount information indicating a power generation amount of the power generation device, and facility information related to a facility present in an area including a position of the base station; and a performance calculation unit configured to calculate the performance based on the power consumption amount information, the power generation amount information, and the facility information acquired by the calculation information acquisition unit.

In the equipment performance calculation device according to the embodiment of the present invention, the performance is calculated based on the power consumption amount information, the power generation amount information, and the facility information. Therefore, with the equipment performance calculation device according to the embodiment of the present invention, it is possible to calculate the performance of the equipment included in the base station in consideration of an environment at the position of the base station. In particular, since the facility information is used for calculation of the performance, it is possible to calculate the performance of the equipment in consideration of the facility present in the area including the position of the base station.

### Advantageous Effects of Invention

According to an embodiment of the present invention, it is possible to calculate the performance of equipment included in the base station in consideration of an environment at the position of the base station.

### BRIEF DESCRIPTION OF DRAWINGS

FIG. 1 is a diagram showing a configuration of an equipment performance calculation device according to an embodiment of the present invention.

FIG. 2 is a diagram showing an example of calculated performances of a power generation device and a storage battery.

FIG. 3 is a table showing an example of information used for estimation of a power generation amount.

FIG. 4 is a table showing an example of information used for calculation of facility information.

FIG. 5 is a flowchart showing processing that is executed by the equipment performance calculation device according to the embodiment of the present invention.

FIG. 6 is a diagram showing a hardware configuration of the equipment performance calculation device according to the embodiment of the present invention.

### DESCRIPTION OF EMBODIMENTS

Hereinafter, embodiments of an equipment performance calculation device according to the present invention will be described in detail with reference to the drawings. In addition, in the description of the drawings, the same elements are denoted by the same reference numerals, and redundant description thereof will be omitted.

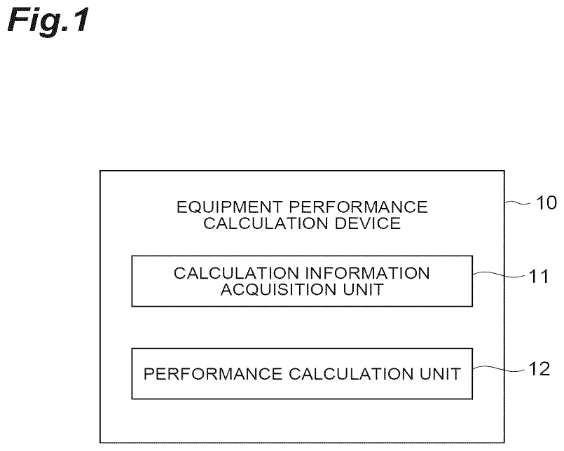

FIG. 1 shows an equipment performance calculation device 10 according to the present embodiment. The equipment performance calculation device 10 is a device (system) that calculates the performance of at least one of a power generation device and a storage battery, which are equipment (devices) included in a base station. The base station is a component of a mobile communication system (mobile communication network) and transmits or receives radio signals to and from a mobile communication terminal. That is, the base station provides a wireless communication function related to the mobile communication system to the mobile communication terminal.

In the present embodiment, the base station where the equipment whose performance is calculated is provided is fixedly installed at a preset geographical position. A power generation device and a storage battery included in the base station are equipment for supplying power for an operation of the base station to the base station. The power generation device is a device that generates power using renewable energy. For example, the power generation device is a solar panel (solar cell panel) that is a solar power generation device that generates power using sunlight. However, the power generation device may be a device that generates power using renewable energy other than the sunlight. The power generation device supplies the power obtained by power generation to the storage battery. Furthermore, the power generation device may be configured to be able to directly supply the power obtained by power generation to the base station. The base station including such a power generation device is also called an environmentally friendly green base station.

The storage battery is a device that receives and stores power generated by a power generation device, and supplies the stored power to the base station. The base station, the power generation device, and the storage battery may be ones of the related art.

A base station including such a power generation device and storage battery can be a completely independent base station that does not rely on commercial power. In the present embodiment, the base station provided with the equipment whose performance is calculated may be a completely independent base station. When the base station is a completely independent base station, it is possible to ensure radio waves, that is, to enable mobile communication in an area where commercial power supply is not secured. This makes it possible to make communications at the time of an emergency or utilize Internet of Things (IoT) terminals in the area.

In the completely independent base station, power for an operation is supplied only from the power generation device and the storage battery. Therefore, the performance of the power generation device and the storage battery needs to be such that the supply of power to the completely independent base station is not interrupted. The equipment performance calculation device 10 calculates the performance of at least one of the power generation device and the storage battery from such a viewpoint. The base station does not necessarily have to be a completely independent base station, and may be one that uses commercial power as long as the base station includes the power generation device and the storage battery (that is, a green base station).

The base station does not need to be one that has already been actually installed at a point in time when the equipment performance calculation device 10 calculates the performance of the at least one of the power generation device and the storage battery, and may be one that will be installed in the future. For example, a result of the performance calculation of the equipment performance calculation device 10 may be used for planning of installation of a new fully independent base station.

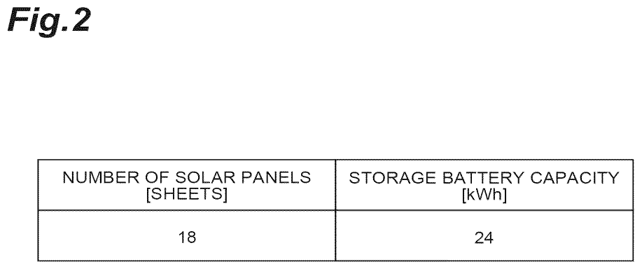

In the present embodiment, the equipment performance calculation device 10 calculates the performance of both the power generation device and the storage battery, as described below. FIG. 2 shows an example of the calculated performance of the power generation device and the storage battery. The calculated performance of the power generation device is, for example, the number of solar panels for which the power generation performance per panel is set in advance. The performance of the storage battery that is calculated is a capacity of the storage battery (for example, in kWh). The calculated performance may be a scale of the facility such as a multiple (for example, number of sheets, number of units) of a preset standard performance, like the performance of the power generation device described above. Further, the calculated performance of the power generation device and the storage battery may be those other than the performance described above as long as the performance of the power generation device and the storage battery can be specified.

The equipment performance calculation device 10 is realized by, for example, a computer such as a personal computer (PC) or a server device. Furthermore, the equipment performance calculation device 10 may be realized by a plurality of computers, that is, a computer system.

Subsequently, functions of the equipment performance calculation device 10 according to the present embodiment will be described. As shown in FIG. 1, the equipment performance calculation device 10 includes a calculation information acquisition unit 11 and a performance calculation unit 12.

The calculation information acquisition unit 11 is a functional unit that acquires power consumption amount information related to a power consumption amount of the base station, power generation amount information indicating a power generation amount of the power generation device, and facility information related to a facility present in an area including a position of the base station. The calculation information acquisition unit 11 may acquire, as the facility information, a parameter according to a type of facility present in the area including the position of the base station. The calculation information acquisition unit 11 may acquire environmental information indicating an environment at a position where the base station is installed, and estimate the power generation amount of the power generation device based on the acquired environmental information to acquire the power generation amount information. The calculation information acquisition unit 11 acquires the power consumption amount information, the power generation amount information, and the facility information as calculation information used for calculation of the performance of equipment. The calculation information acquisition unit 11 acquires each piece of information as follows, for example.

The equipment performance calculation device 10 stores information on a base station and equipment included in the base station in a database or the like in advance, and uses the information to acquire the calculation information. The information stored here may include information on a base station or the like other than the base station related to the calculation of the performance of the equipment. Specific information to be stored and how to use the method will be described later.

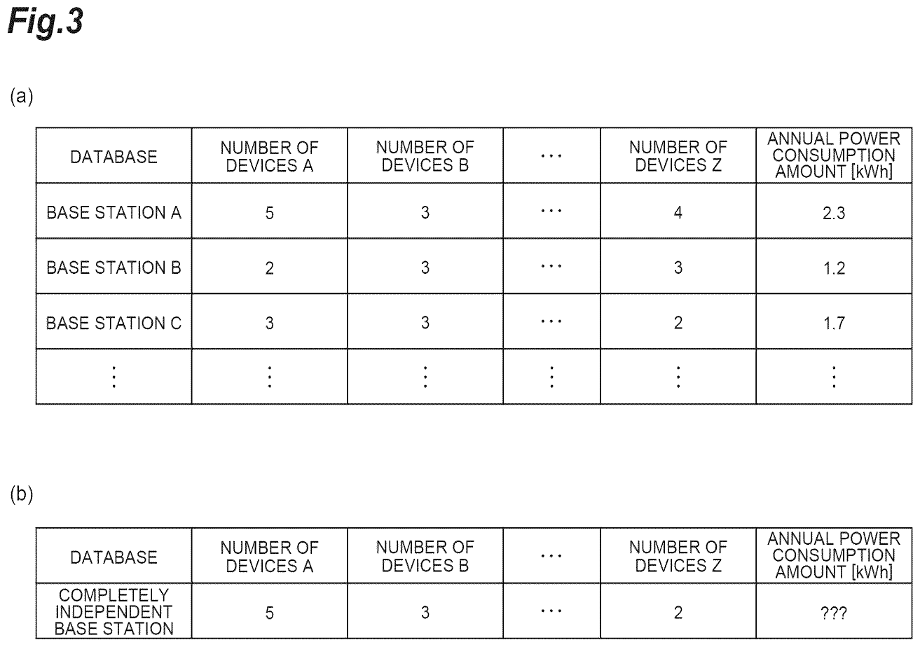

The power consumption amount information acquired by the calculation information acquisition unit 11 is, for example, a power consumption amount (for example, in a unit of kWh) of the base station per unit time (for example, yearly). The equipment performance calculation device 10 stores information indicating a correspondence relationship between a device configuration of the base station and an annual power consumption amount for a green base station that is already in use (other than the base station related to the calculation of the performance of the equipment) in a database or the like. An example of information to be stored is shown in FIG. 3(a). The base station may include a plurality of devices (“device A”, “device B”, . . . “device Z” shown in FIG. 3(a)) (equipment). Each device consumes power to realize a function of the base station, and is, for example, an antenna constituting a cell or a sector of the base station. Information indicating the device configuration of the base station stored in the database is the number of devices included in the base station. The power consumption amount of the base station depends on the above configuration of the device.

The calculation information acquisition unit 11 acquires information indicating the device configuration of the base station related to the calculation of the performance of the equipment. The information is stored in advance in a database by, for example, a user of the equipment performance calculation device 10, and the calculation information acquisition unit 11 acquires the stored information. FIG. 3(b) shows an example of information to be acquired. The calculation information acquisition unit 11 acquires the power consumption amount information from information indicating a correspondence relationship between a device configuration of an existing base station and an annual power consumption amount (information shown in FIG. 3(a)) and the information indicating the device configuration of the base station related to the calculation of the performance of the equipment (information shown in FIG. 3(b)).

For example, the calculation information acquisition unit 11 generates a trained model that receives information indicating a device configuration of a base station and outputs information indicating a power consumption amount from the information indicating the correspondence relationship between the device configuration of the existing base station and the annual power consumption amount (the information shown in FIG. 3(a)) using machine learning. The calculation information acquisition unit 11 inputs the information indicating the device configuration of the base station related to the calculation of the performance of the equipment (the information shown in FIG. 3(b)) to the generated trained model, and calculates the power consumption amount to acquire power consumption amount information. The generation of the trained model itself, the calculation using the trained model, and the like may be performed as in machine learning of the related art.

Alternatively, the calculation information acquisition unit 11 calculates the power consumption amount per device (standard power consumption amount) from the information indicating the correspondence relationship between the device configuration of the existing base station and the annual power consumption amount (the information shown in FIG. 3(a)). The calculation information acquisition unit 11 multiplies the calculated power consumption amount per device by the information indicating the device configuration of the base station related to the calculation of the performance of the equipment (information shown in FIG. 3(b)) to calculate the power consumption amount and acquire power consumption amount information. The calculation of the power consumption amount per each device, and the like may be performed using a statistical method of the related art or the like.

The green base station does not experience a large fluctuation in power consumption over 24 hours. Therefore, advanced prediction of the power consumption amount is not required, and the power consumption amount can be predicted from the device configuration of the base station as described above. However, the acquisition of the power consumption amount information (calculation of the power consumption amount of the base station related to the calculation of the performance of the equipment) need not be performed as described above, and may be performed in any manner. Moreover, the power consumption amount information may be information other than the above, as long as the information can be used for calculation of the performance of the power generation device and the storage battery.

The power generation amount information acquired by the calculation information acquisition unit 11 is, for example, information indicating the power generation amount per unit time in a preset unit scale of a power generation device included in the base station. Specifically, the power generation amount information is a power generation amount per hour (for example, in kWh) when there is sunlight with one solar panel set in advance. It is assumed that the solar panel set in advance is the same as a solar panel whose number is calculated as the performance.

For the green base station that is already in use, the equipment performance calculation device 10 stores information indicating a correspondence relationship between a power generation amount of the solar panel included in the base station and the environmental information indicating an environment at the position where the base station is installed, in the database or the like. This power generation amount of the solar panel is a power generation amount per unit time in a preset unit scale, similarly to the power generation amount related to the power generation amount information.

The environmental information indicating the environment at the position where the base station is installed is, for example, information indicating a meteorological environment at the position. The information indicating the meteorological environment may be time-series information over a preset period (for example, the past 10 years). The information indicating the meteorological environment is, for example, information on atmospheric pressure, relative humidity, temperature, cloud amount, weather, daylight hours, and daily precipitation. Among the above information, information of atmospheric pressure, relative humidity, temperature, cloud amount, weather, and daylight hours is, for example, information on an hourly basis. Moreover, the information on daylight hours and daily precipitation is, for example, information on a daily basis. Each piece of information other than information on the weather is expressed as a numerical value. Information on the weather W is information indicating a type of weather (sunny, cloudy, or the like). Information indicating the meteorological environment in each region is acquired from an external source such as a database of a meteorological agency, for example. Furthermore, the environmental information may include time-series sunlight intensity data at the position.

The environmental information indicating the environment at the position where the base station is installed may be an average value of environmental information indicating an environment at observation points within a preset range centered on the position. Alternatively, when there is no observation point within the range, the environmental information of the observation point closest to the position may be used.

The calculation information acquisition unit 11 acquires environmental information indicating the environment at the position where the base station related to the calculation of the performance of the equipment is installed. The environmental information is information (meteorological information) indicating the meteorological environment in the area including the position, similar to the above-described meteorological information. The environmental information indicating the environment at the position where the base station related to the calculation of the performance of the equipment is installed is stored in the database in advance by, for example, the user of the equipment performance calculation device 10, and the calculation information acquisition unit 11 acquires the stored information.

The calculation information acquisition unit 11 acquires the power generation amount information from, for an existing green base station, the information indicating the correspondence relationship between the power generation amount of the solar panel included in the base station and the environmental information indicating the environment at the position where the base station is installed, and the environmental information indicating the environment at the position where the base station related to the calculation of the performance of the equipment is installed.

For example, the calculation information acquisition unit 11 extracts an existing green base station with a meteorological environment similar to that of the base station related to the calculation of the performance of the equipment. The calculation information acquisition unit 11 calculates, for each existing green base station whose information is stored in the database, the following score (evaluation index) indicating a degree of similarity of the meteorological environment to that of the base station related to the calculation of the performance of the equipment.

$$\sum ( {P}_{t} + {S}_{t} + {T}_{t} + {C}_{t} + {W}_{t} ) + \sum ( L + R ) \qquad [ Math . 1 ]$$

Pₜ, Sₜ, Tₜ, Cₜ, Wₜ, L, and R in the above score are difference scores of information indicating respective meteorological environments between the base station related to the calculation of the performance of the equipment and the green base station. The difference score has a greater value when the meteorological environments of the base station related to the calculation of the performance of the equipment and the green base station are closer (for example, when a difference in numerical values indicating the meteorological environment is smaller). For example, the difference score can be calculated by inputting information (for example, numerical values) indicating the meteorological environments of the base station related to the calculation of the performance of the equipment and the green base station to a preset calculation equation for calculating the difference score.

Meanings of the respective variables in the above score are as follows.
Pₜ: Difference score of atmospheric pressure at time t (for example, every hour as described above, the same applies hereinafter)
Sₜ: Difference score of relative humidity at time t
Tₜ: Difference score of temperature at time t
Cₜ: Difference score of cloud amount at time t
Wₜ: Difference score of weather at time t
L: Difference score of daylight hours
R: Difference score of daily precipitation

As described above, since the daylight hours and the daily precipitation are daily information (numerical values), L and R are also daily numerical values. In addition, Σ indicating a sum of the scores indicates a sum of the difference scores related to the above-described preset period (for example, the past 10 years).

The calculation information acquisition unit 11 extracts the existing green base station with the highest calculated score as a green base station with a meteorological environment similar to that of the base station related to the calculation of the performance of the equipment. The calculation information acquisition unit 11 sets the power generation amount of the solar panel associated with the environmental information of the extracted green base station in a correspondence relationship stored in advance as an estimated amount of the power generation amount of the solar panel included in the base station related to the calculation of the performance of the equipment. The calculation information acquisition unit 11 acquires information indicating this power generation amount as the power generation amount information. This is because, when the meteorological environment is the same, the power generation amounts of the solar panels are expected to be the same.

As described above, the calculation information acquisition unit 11 performs pattern matching using the environmental information to acquire the power generation amount information. However, the power generation amount information does not need to be acquired as described above, and may be acquired by using any method. For example, the power generation amount information may be acquired by simulating power generation of a solar panel using data of power generation of existing solar panels. Further, the power generation amount information may be information other than the above, as long as the information can be used for calculation of the performance of the power generation device and the storage battery.

The facility information acquired by the calculation information acquisition unit 11 is for considering facilities present in the area including the position of the base station in calculating the performance of the power generation device and the storage battery. Whether or not the base station is always functioning, that is, whether or not it is necessary to keep the base station in the area at all times depends on attributes of a geographical area including an installation place, specifically, facilities (buildings) present in the area. For example, when a facility where many people gather, such as an elementary school, a station, or a commercial building, is present in the area, it is assumed that, if the base station stops functioning and stops transmitting, an impact thereof is large. Therefore, when the base station, particularly, the completely independent base station is installed in such an area, a larger number of solar panels and a larger storage battery capacity are required to prevent functions of the base station from stopping due to power shortages, as compared to a base station without such a facility.

The facility information is a parameter k according to the type of facility present in the area including the position of the base station related to the calculation of the performance of the equipment. When a value of the parameter κ is greater, a larger number of solar panels and a larger storage battery capacity are required for the base station. The calculation information acquisition unit 11 acquires the parameter κ as follows, for example.

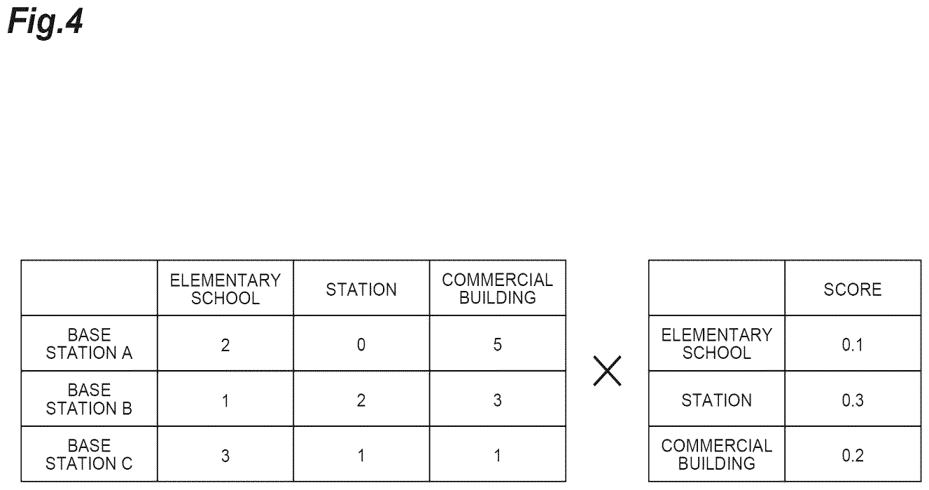

The calculation information acquisition unit 11 acquires information indicating the number of facilities of each type present in the area including the position of the base station related to the calculation of the performance of the equipment. The area is, for example, an area where mobile communication is performed using the base station, and is set in advance. The types of facilities related to the information are set in advance, and are an elementary school, a station, a commercial building, and the like. A table on the left side of FIG. 4 shows an example of the information indicating the number of facilities for each type. Although the table on the left side of FIG. 4 is an example of information related to three base stations, it is sufficient to acquire information on the base stations related to the calculation of the performance of the equipment in the calculation. The calculation information acquisition unit 11 acquires the information, for example, by receiving an input operation from the user of the equipment performance calculation device 10.

The calculation information acquisition unit 11 stores a score (coefficient) for each type of facility in advance. A table on the right side of FIG. 4 shows an example of a coefficient for each type of facility. The score has a greater value when an impact when the base station stops functioning, that is, an impact when mobile communication cannot be performed in the facility of the type is large. The calculation information acquisition unit 11 multiplies the number of facilities for each type indicated by the acquired information by the score of the type, calculates a sum value (total value), and sets the value as the parameter κ. For example, in the example of a base station A shown in FIG. 4, 2 (number of elementary schools)×0.1 (score of elementary schools)+0 (number of stations)×0.3 (score of stations)+5 (number of commercial buildings)×0.2 (score of commercial building)=1.2 is the value of the parameter κ.

The acquisition of the facility information does not need to be performed as described above, and may be performed using any method. Further, the facility information may be information other than the above as long as the information can be used for calculation of the performance of the power generation device and the storage battery. The calculation information acquisition unit 11 outputs the acquired power consumption amount information, power generation amount information, and facility information to the performance calculation unit 12.

The performance calculation unit 12 is a functional unit that calculates the performance based on the power consumption amount information, the power generation amount information, and the facility information acquired by the calculation information acquisition unit 11. The performance calculation unit 12 may calculate the performance using a pre-stored calculation equation for calculating the performance, which includes the parameter according to the type of facility acquired by the calculation information acquisition unit 11 as a variable. The performance calculation unit 12 calculates the performance as follows.

The performance calculation unit 12 receives the power consumption amount information, the power generation amount information, and the facility information from the calculation information acquisition unit 11. The performance calculation unit 12 calculates the number X of solar panels (for example, in units of sheets in the following equation) and a capacity Y of the storage battery (for example, in kWh in the following equation) through the following equation using the received pieces of information.

$$\begin{matrix}Y = α ( β + δ κ ) \\ X = [ \frac{Y}{{P}_{i} γ} ]\end{matrix} \qquad [ Math . 2 ]$$

A meaning of each variable in the above calculation equation is as follows.
Pᵢ: Power generation amount [kWh] per hour in one solar panel at the green base station i whose meteorological environment is most similar to that of the base station related to the calculation of the performance of the equipment
α: Daily power consumption amount [kWh] of the base station related to the calculation of the performance of the equipment
β: Average number [days] of consecutive days in which the daylight hours are less than a preset time in past data of the position of the base station related to the calculation of the performance of the equipment
γ: Average daylight hours per day at the position of the base station related to the calculation of the performance of the equipment [h]
κ: Total value of facility scores for each type
δ: Supplementary time [days]

Pᵢ is a value indicated by the power generation amount information. α is a value obtained by dividing the annual power consumption amount of the base station indicated by the power consumption amount information by the number of days in the year. κ is a value indicated by the facility information. β and γ are information obtained from the above-described environmental information stored in the database in advance. δ is a preset value, and is a value related to margins of the number of solar panels and the capacity of the storage battery. When δ becomes greater, the margins of the number of solar panels and the capacity of the storage battery become larger.

The above calculation equation is intended to ensure that the power consumption of the base station can be covered by the power generated by the solar panel and stored in the storage battery. Further, in the above calculation equation, the number of solar panels and the capacity of the storage battery to be calculated are based on the facility present in the area including the position of the base station related to the calculation of the performance of the equipment. Specifically, when an impact in a case where mobile communication becomes unavailable at the facility is greater, the number of solar panels and the capacity of the storage battery are larger.

The performance calculation does not necessarily need to be performed using the above calculation equation, and may be performed in any manner as long as the calculation is based on the power consumption amount information, the power generation amount information, and the facility information. For example, the preset δ may be set in consideration of seasonal factors and the like.

Further, β in the calculation equation may be a maximum

number of consecutive days [days] where the daylight hours are less than a preset time, instead of an average number of consecutive days [days] where the daylight hours is less than the preset time. Alternatively, γ in the calculation equation may be average daylight hours [h] per day in a preset short period of daylight hours, instead of average daylight hours [h] per day in an entire period. With such a calculation, it is possible to calculate the number of solar panels and the capacity of the storage battery in which a case where the daylight hours are short is considered more strongly.

Further, although the calculation has been performed using the information related to only one existing green base station with the most similar meteorological environment to that of the base station related to the calculation of the performance of the equipment in the above example, the calculation may be performed using information related to a plurality of existing green base stations with top scores. In this case, the performance may be calculated by taking an average of the information related to the plurality of existing green base stations, or the performance may be calculated as a plurality of candidates for each piece of information related to the plurality of existing green base stations.

The performance calculation unit 12 outputs information indicating the calculated performance using a preset method. The performance calculation unit 12 may display the information indicating the calculated performance on a display device included in the equipment performance calculation device 10 so that the user of the equipment performance calculation device 10 can refer to the information. The user of the equipment performance calculation device 10 can determine the number of solar panels and the capacity of the storage battery included in the base station by referring to the information. Alternatively, the installation of the base station itself can be determined. Furthermore, the performance calculation unit 12 may output the information by using a method other than the above. For example, the performance calculation unit 12 may transmit information to another device, module, or the like. The above is a function of the equipment performance calculation device 10 according to the present embodiment.

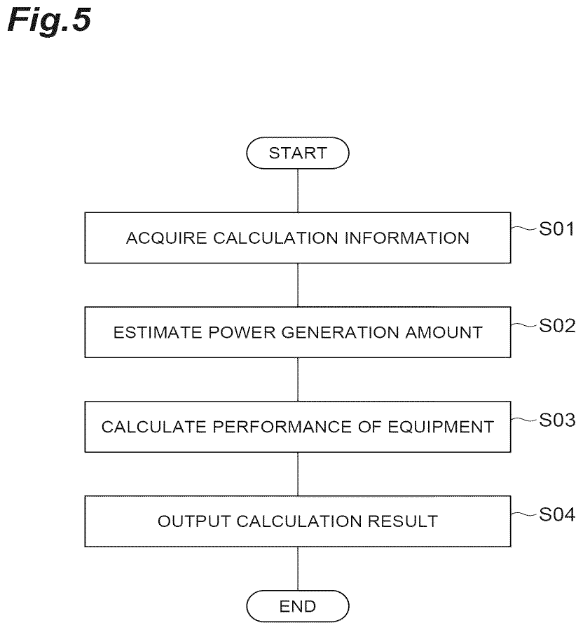

Subsequently, processing that is executed by the equipment performance calculation device 10 according to the present embodiment (an operation method performed by the equipment performance calculation device 10) will be described using the flowchart of FIG. 5. In the present processing, first, the calculation information acquisition unit 11 acquires the calculation information used for calculation of the performance of the equipment (S01). Specifically, power consumption amount information related to the base station related to the calculation of the performance of the equipment and facility information related to the facility present in the area including the position of the base station are acquired. Further, the environmental information indicating the environment at the position where the base station is installed is acquired.

Subsequently, the calculation information acquisition unit 11 estimates the power generation amount of the power generation device based on the environmental information and acquires the power generation amount information (S02). Subsequently, the performance calculation unit 12 calculates the performance of the equipment, specifically, the number of solar panels and the capacity of the storage battery, based on the power consumption amount information, the power generation amount information, and the facility information (S03). Subsequently, the performance calculation unit 12 outputs information indicating the calculated performance of the equipment (S04). The above is the processing executed by the equipment performance calculation device 10 according to the present embodiment.

In the present embodiment, the performance of equipment is calculated based on the power consumption amount information, the power generation amount information, and the facility information. Therefore, according to the present embodiment, it is possible to calculate the performance of the equipment included in the base station in consideration of the environment at the position of the base station. In particular, since the facility information is used for calculation of the performance, it is possible to calculate the performance of the equipment in consideration of the facilities present in the area including the position of the base station.

Furthermore, the performance may also be calculated by using a calculation equation including the parameter according to the type of facility as a variable, using the parameter according to a type of facility present in the area including the position of the base station as the facility information, as in the present embodiment. According to this configuration, it is possible to appropriately consider the facility present in the area and to calculate the performance of the facility reliably and appropriately. However, the facility information does not need to be the parameter according to the type of facility present in the area including the position of the base station, but may be any information as long as the information is information related to the facility present in the area including the position of the base station. Furthermore, a method of considering facility information may be a method other than a method using a calculation equation.

Furthermore, as in the present embodiment, the power generation device may be a solar power generation device such as a solar panel. However, the power generation device may be a device other than the solar power generation device.

Furthermore, the power generation amount information may be acquired by estimating the power generation amount of the power generation device based on the environmental information, as in the present embodiment. With this configuration, even when the power generation amount information cannot be directly acquired, it is possible to acquire the power generation amount information reliably and appropriately. As a result, it is possible to calculate the performance of the equipment reliably and appropriately. However, the estimation of the power generation amount based on the environmental information does not necessarily have to be performed, and the power generation amount information may be acquired in any manner.

Although the equipment performance calculation device 10 has calculated the performance of both the power generation device and the storage battery in the embodiment described above, the equipment performance calculation device 10 may calculate the performance of only one of the power generation device and the storage battery. In this case, the calculation may be performed using, for example, a calculation equation for calculating the performance of only one of the power generation device and the storage battery.

The block diagram used for the description of the embodiment shows blocks in functional units. These functional blocks (components) are realized by any combination of at least one of hardware and software. Further, a method for realizing each functional block is not particularly limited. That is, each functional block may be realized using one physically or logically coupled device, or may be realized connecting two or more physically or logically separated devices by directly or indirectly (for example, using wired or wireless) and using these plurality of devices. The functional block may be realized by combining software with the one device or the plurality of devices.

The functions include judging, determining, decision, calculating, computing, processing, deriving, investigating, searching, confirming, receiving, transmitting, outputting, accessing, resolving, selecting, choosing, establishing, comparing, assuming, expecting, considering, broadcasting, notifying, communicating, forwarding, configuring, reconfiguring, allocating or mapping, assigning, and the like, but are not limited thereto. For example, a functional block (constituent unit) that causes transmission to function is called a transmission unit or transmitter. In either case, the realization method is not particularly limited, as described above.

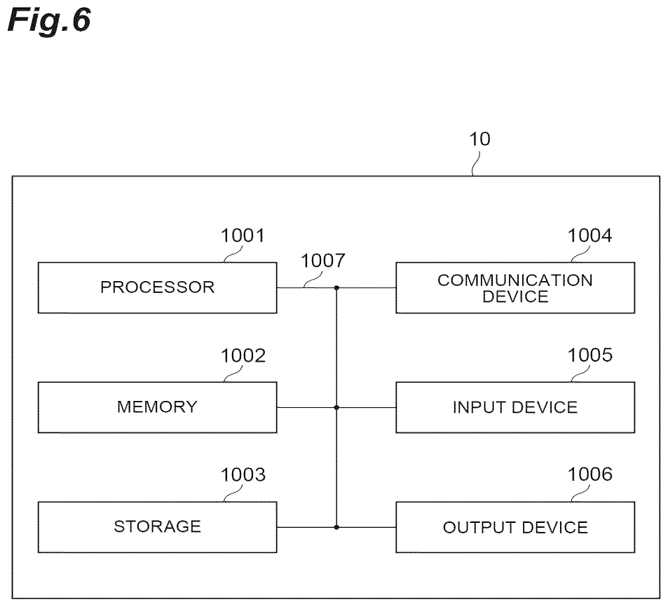

For example, the equipment performance calculation device 10 in one embodiment of the present disclosure may function as a computer that performs information processing of the present disclosure. FIG. 6 is a diagram illustrating an example of a hardware configuration of the equipment performance calculation device 10 according to the embodiment of the present disclosure. The equipment performance calculation device 10 described above may be physically configured as a computer device including a processor 1001, a memory 1002, a storage 1003, a communication device 1004, an input device 1005, an output device 1006, a bus 1007, and the like.

In the following description, the word “device” can be read as a circuit, a unit, or the like. A hardware configuration of the equipment performance calculation device 10 may be configured to include one or a plurality of respective devices shown in the figures, or may be configured without including some of the devices.

Each function in the equipment performance calculation device 10 is realized by the processor 1001 performing computing by predetermined software (programs) being loaded onto hardware such as the processor 1001 and the memory 1002 to control communication using the communication device 1004, or by controlling at least one of data reading and writing in the memory 1002 and the storage 1003.

The processor 1001 controls the entire computer by operating an operating system, for example. The processor 1001 may be configured by a central processing unit (CPU) including an interface with peripheral devices, a control device, a computing device, registers, and the like. For example, each function in the above-described equipment performance calculation device 10 may be realized by the processor 1001.

Furthermore, the processor 1001 reads a program (program codes), software modules, data, or the like from at least one of the storage 1003 and the communication device 1004 to the memory 1002, and executes various types of processing according to these. As the program, a program for causing the computer to execute at least some of the operations described in the above embodiments may be used. For example, each function in the equipment performance calculation device 10 may be realized by a control program stored in the memory 1002 and operated in the processor 1001. Although the various types of processing described above have been described as being executed by one processor 1001, the various types of processing may be executed by two or more processors 1001 simultaneously or sequentially. The processor 1001 may be implemented by one or more chips. The program may be transmitted from a network via a telecommunication line.

The memory 1002 is a computer-readable recording medium, and may be configured of at least one of a read only memory (ROM), an erasable programmable ROM (EPROM), an electrically erasable programmable ROM (EEPROM), a random access memory (RAM), and the like. The memory 1002 may be called a register, cache, main memory (main storage device), or the like. The memory 1002 can store executable programs (program codes), software modules, and the like to implement information processing according to an embodiment of the present disclosure.

The storage 1003 is a computer-readable recording medium, and may be configured of at least one of an optical disc such as a compact disc ROM (CD-ROM), a hard disk drive, a flexible disk, or a magneto-optical disk (for example, a compact disc, a digital versatile disc, or a Blu-ray (registered trademark) disc), a smart card, a flash memory (for example, a card, a stick, or a key drive), a floppy (registered trademark) disk, magnetic strip, and the like. The storage 1003 may also be called an auxiliary storage device. The storage medium included in the equipment performance calculation device 10 may be, for example, a database including at least one of the memory 1002 and the storage 1003, a server, or other appropriate medium.

The communication device 1004 is hardware (transmission and reception device) for performing communication between computers via at least one of a wired network and a wireless network, and is also referred to as a network device, network controller, network card, communication module, or the like, for example.

The input device 1005 is an input device (for example, a keyboard, a mouse, a microphone, switch, a button, or a sensor) that receives input from the outside. The output device 1006 is an output device (for example, a display, a speaker, or an LED lamp) that performs output to the outside. The input device 1005 and the output device 1006 may be an integrated configuration (for example, a touch panel).

Further, each device such as the processor 1001 and the memory 1002 is connected by a bus 1007 for communicating information. The bus 1007 may be configured using a single bus, or may be configured using different buses for each device.

Further, the equipment performance calculation device 10 may include hardware such as a microprocessor, a digital signal processor (DSP), an application specific integrated circuit (ASIC), a programmable logic device (PLD), and a field programmable gate array (FPGA), and some or all of respective functional block may be realized by the hardware. For example, the processor 1001 may be implemented using at least one of these pieces of hardware.

Each aspect/embodiment described in the present disclosure may be applied to at least one of a system using Long Term Evolution (LTE), LTE-Advanced (LTE-A), SUPER 3G, IMT-Advanced, 4th generation mobile communication system (4G), 5th generation mobile communication system (5G), Future Radio Access (FRA), new Radio (NR), W-CDMA (registered trademark), GSM (registered trademark), CDMA2000, Ultra Mobile Broadband (UMB), IEEE 802.11 (Wi-Fi (registered trademark)), IEEE 802.16 (WiMAX (registered trademark)), IEEE 802.20, UWB (Ultra-WideBand), Bluetooth (registered trademark), and another appropriate system, and a next generation system expanded based on these. Furthermore, a combination of a plurality of systems (for example, a combination of at least one of LTE and LTE-A with 5G) may be applied.

An order of processing procedures, sequences, flowcharts, or the like of each aspect/embodiment described in the present disclosure may be changed as long as there is no contradiction. For example, for the methods described in the present disclosure, elements of various steps are present using an example order and are not limited to a presented specific order.

The input and output information may be stored in a specific place (for example, memory) or may be managed using a management table. Information or the like to be input and output may be overwritten, updated, or additionally written. The output information or the like may be deleted. The input information or the like may be transmitted to other devices.

The determination may be performed using a value expressed by 1 bit (0 or 1), may be performed using a truth value (Boolean: true or false), or may be performed using a comparison of numerical values (for example, comparison with a predetermined value).

Each aspect/embodiment described in the present disclosure may be used alone, may be used in combination, or may be switched and used depending on execution. Further, notification of predetermined information (for example, notification of “being X”) is not limited to being performed explicitly, but may also be performed implicitly (for example, non-notification of the predetermined information).

Although the present disclosure has been described in detail above, it is clear for those skilled in the art that the present disclosure is not limited to the embodiments described in the present disclosure. The present disclosure can be implemented as modification and variation aspects without departing from the spirit and scope of the present disclosure as determined by the claims. Therefore, the description of the present disclosure is for the purpose of illustrative description and is not intended to have any limiting meaning with respect to the present disclosure.

The software should be broadly construed to mean instruction, instruction set, code, code segment, program code, program, subprogram, software module, application, software application, software package, routine, subroutine, object, executable file, execution thread, procedure, function, or the like whether referred to as software, firmware, middleware, microcode, hardware description language, or by any other name.

Further, software, instructions, information, or the like may be transmitted and received via a transmission medium. For example, when the software is transmitted using at least one of wired technology (coaxial cable, fiber optic cable, twisted pair, digital subscriber line (DSL), or the like) and wireless technology (infrared, microwave, or the like) from a website, a server or another remote source, the at least one of the wired technology and the wireless technology is included within a definition of the transmission medium.

The terms “system” and “network” as used in the present disclosure are used interchangeably.

Further, the information, parameter, or the like described in the present disclosure may be expressed using an absolute value, may be expressed using a relative value from a predetermined value, or may be expressed using other corresponding information.

The terms “determining” as used in the present disclosure may encompass a wide variety of operations. The “determining” may include, for example, that judging, calculating, computing, processing, deriving, investigating, looking up, search, or inquiry (for example, searching in a table, database, or other data structure), and ascertaining is regarded as being “determined.” Further, “determining” may include that receiving (for example, receiving information), transmitting (for example, transmitting information), input, output, and accessing (for example, accessing data in a memory) is regarded as being “determined.” Further, “determining” may include that resolving, selecting, choosing, establishing, comparing, or the like is regarded as being “determined”. That is, “determining” may include that some operation is regarded as being “determined.” Further, “determining” may be read as “assuming”, “expecting”, “considering”, or the like.

The terms “connected”, “coupled”, or any variations thereof refer to any direct or indirect connection or coupling between two or more elements, and can include the presence of one or more intermediate elements between two elements that are “connected” or “coupled” to each other. Coupling or connection between elements may be physical, logical, or a combination thereof. For example, “connection” may be replaced with “access.” As used in the present disclosure, two elements can be considered as being “connected” or “coupled” by using at least one of one or more electrical wires, cables, and/or printed electrical connections, and using, for example, electromagnetic energy having wavelengths in a radio frequency domain, a microwave domain, and an optical domain (both visible and non-visible domains) as some non-limiting and non-inclusive examples.

The phrase “based on” as used in the present disclosure does not mean “based solely on” unless explicitly stated otherwise. In other words, the phrase “based on” means both “based only on” and “based at least on.”

Any reference to elements using terms “first,” “second,” or the like as used in the present disclosure does not generally limit an amount or order of the elements. These terms may be used in the present disclosure as a convenient way to distinguish between two or more elements. Thus, reference to a first and second element does not mean that only two elements may be employed or that the first element must precede the second element in any way.

When “include”, “including”, and variations thereof are used in the present disclosure, these terms are intended to be inclusive, like the term “comprising.” Furthermore, the term “or” as used in the present disclosure is intended not to be exclusive OR.

In the present disclosure, when articles are added by translation, like a, an, and the in English, the present disclosure may include that nouns following these articles are plural.

In the present disclosure, the term “A and B are different” may mean “A and B are different from each other.” The term may also mean that “each of A and B are different from C”. Terms such as “separated” and “coupled” may also be interpreted similarly to “different.”

### REFERENCE SIGNS LIST

10 Equipment performance calculation device
11 Calculation information acquisition unit
12 Performance calculation unit
1001 Processor
1002 Memory
1003 Storage
1004 Communication device
1005 Input device
1006 Output device
1007 Bus

1. An equipment performance calculation device for calculating the performance of at least one of a power generation device and a storage battery for a base station including the power generation device using renewable energy and the storage battery, the equipment performance calculation device comprising circuitry configured to:
acquire power consumption amount information related to a power consumption amount of the base station, power generation amount information indicating a power generation amount of the power generation device, and facility information related to a facility present in an area including a position of the base station; and
calculate the performance based on the acquired power consumption amount information, the power generation amount information, and the facility information.

2. The equipment performance calculation device according to claim 1, wherein
the circuitry acquires, as the facility information, a parameter according to a type of facility present in the area including the position of the base station, and
calculates the performance using a pre-stored calculation equation for calculating the performance, the calculation equation including, as a variable, the acquired parameter according to a type of facility.

3. The equipment performance calculation device according to claim 1, wherein the power generation device is a solar power generation device.

4. The equipment performance calculation device according to claim 1, wherein the circuitry acquires environmental information indicating an environment at a position where the base station is installed, and estimates the power generation amount of the power generation device based on the acquired environmental information to acquire the power generation amount information.

5. The equipment performance calculation device according to claim 2, wherein the power generation device is a solar power generation device.
